(19) United States
(12) Patent Application Publication
(10) Pub. No.: US 2009/0115004 A1
(43) Pub. Date: May 7, 2009

(54) SURFACE ACOUSTIC WAVE SENSOR ASSEMBLIES

(75) Inventors: Chad J. Carter, Lake Elmo, MN (US); Michael B. Free, St. Paul, MN (US); John S. Huizinga, White Bear Lake, MN (US); Raymond P. Johnston, Lake Elmo, MN (US)

Correspondence Address: 3M INNOVATIVE PROPERTIES COMPANY, PO BOX 33427, ST. PAUL, MN, 55133-3427, US

(73) Assignee: 3M INNOVATIVE PROPERTIES COMPANY, Saint Paul, MN (US)

(21) Appl. No.: 10/596,954

(22) PCT Filed: Dec. 17, 2004
(86) PCT No.: PCT/US2004/042663

§ 371 Date: Jan. 22, 2009

Related U.S. Application Data
(60) Provisional application No. 60/533,176, filed on Dec. 30, 2003.

(51) Int. Cl. G01N 29/02; H01L 41/107

(52) U.S. Cl. 257/414; 310/313 C; 257/E23.132

(57) ABSTRACT

The invention is directed to a surface acoustic wave sensor assembly that makes use of a Z-axis conductive layer, such as a Z-axis conductive elastomer, or the like. In particular, a Z-axis conductive elastomer couples a circuit layer to a surface acoustic wave (SAW) sensor in order to form a SAW sensor assembly. For example, a plurality of electrical contacts of the circuit layer can be coupled to a plurality of electrodes of the SAW sensor via the Z-axis conductive elastomer. The Z-axis conductive elastomer provides electrical coupling between the electrical contacts and the electrodes, and also forms a hermetic barrier between the circuit layer and the SAW sensor. In addition, elastic properties of the Z-axis conductive elastomer may reduce pressure exerted on the SAW sensor during use.

### RELATED APPLICATIONS

This application claims priority to U.S. Provisional Patent Application No. 60/533,176, filed on Dec. 30, 2003, which is incorporated herein by reference in its entirety.

The invention relates to surface acoustic wave (SAW) sensors and, more particularly, to techniques for coupling a SAW sensor to a circuit.

Chemical and biological testing is commonly used to test for the presence or absence of chemical or biological agents. Testing for the presence of chemical or biological agents in blood, food or other materials is generally performed to ensure safety or to facilitate diagnosis of medical conditions. For example, testing is used to identify chemicals, bacteria or other agents in blood samples taken from medical patients, laboratory samples developed for experimental purposes, food samples, or the like. In addition, chemical and biological testing is also used to test for medical conditions such as pregnancy, diabetes, and a wide variety of other conditions that may affect the patient's chemistry or biology.

One type of sensor that has been developed for chemical or biological sensing capabilities is a surface acoustic wave (SAW) sensor. One example of a SAW is a Love mode shear-horizontal surface acoustic wave (SH-SAW) sensor. A SH-SAW sensor includes four main components: 1) a piezoelectric substrate; 2) an input inter-digitated transducer (IDT) on the substrate, which is used to excite an acoustic wave based on the piezoelectric effect; 3) an output IDT on the substrate, which receives the transmitted acoustic wave and generates electrical output by exploiting the piezoelectric effect; and 4) a wave-guide layer over the IDT's, which converts SH-type waves into waveguide Love modes for transmission from the input IDT to the output IDT. The presence of one or more materials on the surface of the SH-SAW affects wave propagation through the waveguide layer, which facilitates detection of the given agent.

In operation, a SAW sensor is electrically coupled to a circuit, which sends signals to the SAW and receives signals from the SAW. In particular, the circuit typically includes circuit traces that are soldered to electrodes of the SAW. In this manner, electrical signals can be sent to the SAW in order to drive the SAW and received from the SAW for processing by the circuit.

### SUMMARY

In general, the invention is directed to a surface acoustic wave sensor (SAW) assembly that makes use of a Z-axis conductive layer, such as a Z-axis conductive elastomer, or the like. In particular, a Z-axis conductive elastomer couples a circuit layer to a SAW sensor in order to form a SAW sensor assembly. For example, a plurality of electrical contacts of the circuit layer can be coupled to a plurality of electrodes of the SAW sensor via the Z-axis conductive elastomer. The Z-axis conductive elastomer provides electrical coupling between the electrical contacts and the electrodes, and may also form a hermetic barrier between the circuit layer and the SAW sensor. Moreover, because of its elastic properties, the Z-axis conductive elastomer may reduce pressure exerted on the SAW sensor during use.

The circuit layer can be formed with an aperture, and the SAW sensor can be coupled to the circuit layer proximate the aperture such that the SAW sensor is accessible through the aperture. If the Z-axis conductive elastomer also forms a hermetic barrier between the circuit layer and the SAW sensor, fluid flowing over the aperture can be sensed by the SAW sensor without contacting the circuitry of the circuit layer. Accordingly, the invention may be useful for detection of chemical or biological agents carried in a fluid.

The described SAW sensor assembly may form part of a sensor cartridge. In that case, a fluid path formed in a cartridge housing allows fluid to flow within the aperture in the circuit layer and over a waveguide layer such that the SAW sensor can detect one or more biological or chemical agents in the fluid. The Z-axis conductive elastomer may also form a hermetic barrier between the circuit layer and the SAW sensor so that fluid sensed by the SAW sensor does not come into contact with the circuitry of the circuit layer.

In one embodiment, the invention provides a SAW sensor assembly comprising a SAW sensor including a plurality of electrodes, a circuit layer including an aperture and a plurality of electrical contacts, and a Z-axis conductive layer to couple the electrical contacts to the electrodes.

In another embodiment, the invention provides a sensor cartridge including a housing with a fluid path, and a SAW sensor assembly including a SAW sensor with a plurality of electrodes, a circuit layer with an aperture and a plurality of electrical contacts, and a Z-axis conductive layer to couple the electrical contacts to the electrodes, wherein the SAW sensor is exposed to the fluid path via the aperture.

In another embodiment, the invention provides a method of forming a SAW assembly that includes electrically coupling a plurality of electrodes of a SAW sensor to a plurality of electrical contacts of a circuit layer with a Z-axis conductive layer.

The invention may be capable of providing a number of advantages. In particular, use of a Z-axis conductive layer may simplify assembly and electrical coupling between a SAW sensor and a circuit layer. Moreover, a Z-axis conductive elastomer may provide a hermetic seal between the SAW sensor and a circuit layer, making the SAW assembly more compatible with fluids. Also, use of a Z-axis conductive elastomer may mechanically isolate the SAW sensor, e.g., from a rigid sensor cartridge housing, such that the SAW sensor is free to move slightly in response to pressure exerted by a fluid flow over the sensor.

The details of one or more exemplary embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1 is an exploded perspective view illustrating an exemplary surface acoustic wave (SAW) sensor assembly according to an embodiment of the invention.

FIG. 2 is a perspective view illustrating the exemplary SAW sensor assembly.

FIG. 3 is a bottom view illustrating the exemplary SAW sensor assembly.

FIG. 4 is a cross-sectional side view illustrating the exemplary SAW sensor assembly.

FIG. 5 is a cross-sectional side view illustrating an exemplary sensor cartridge according to an embodiment of the invention.

FIG. 6 is another cross-sectional side view illustrating an exemplary sensor cartridge according to an embodiment of the invention.

### DETAILED DESCRIPTION OF EXEMPLARY EMBODIMENTS OF THE INVENTION

The invention is directed to a surface acoustic wave (SAW) sensor assembly that makes use of a Z-axis conductive layer, such as a Z-axis conductive elastomer, or the like. A Z-axis conductive elastomer generally refers to an elastomeric material loaded with conductive particles that generate a conductive path across the thickness of the elastomeric material. While an elastomer is used in many embodiments, suitable materials for the Z-axis conductive layer may also include those described in U.S. Pat. No. 5,685,939 (Wolk et al.); U.S. Pat. No. 5,362,421 (Kropp et al.) and U.S. Publication No. 2001/0028953 A1.

In accordance with one embodiment of the invention, a Z-axis conductive elastomer couples a circuit layer to a SAW sensor in order to form a SAW sensor assembly. For example, a plurality of electrical contacts of the circuit layer can be coupled to a plurality of electrodes of the SAW sensor via the Z-axis conductive elastomer. The Z-axis conductive elastomer provides the electrical connection between the electrical contacts and the electrodes, and also forms a hermetic barrier between the circuit layer and the SAW sensor. Moreover, because of its elastic properties, the Z-axis conductive elastomer may reduce pressure exerted on the SAW sensor during use.

The circuit layer includes an aperture, and the SAW sensor is coupled to the circuit layer proximate the aperture such that the SAW sensor is accessible through the aperture. Fluid flowing over the aperture can preferably be sensed by the SAW sensor without affecting the circuitry of the circuit layer because the Z-axis conductive elastomer forms a hermetic barrier between the circuit layer and the SAW sensor. In particular, the Z-axis conductive elastomer blocks migration of the fluid from the sensor to the circuitry, thereby preventing electrical short circuits. Accordingly, the invention can facilitate the use of SAW sensors in fluidic environments.

The SAW sensor assembly may form part of a sensor cartridge that receives or contains a fluid to be tested. A fluid path formed in the cartridge allows fluid to flow past the aperture in the circuit layer such that the SAW sensor can detect one or more biological or chemical agents in the fluid. Again, the Z-axis conductive elastomer preferably forms a hermetic barrier between the circuit layer and the SAW sensor so that fluid sensed by the SAW sensor does not come into contact with the circuitry of the circuit layer. At the same time, however, the Z-axis conductive elastomer permits electrical conduction between electrodes associated with the SAW sensor and circuit elements within the circuit layer.

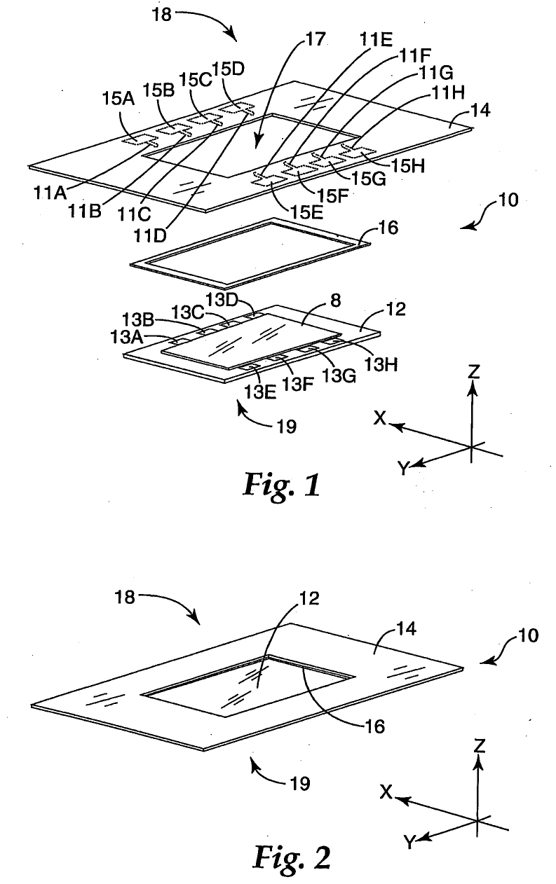

FIG. 1 is an exploded perspective view illustrating an exemplary SAW sensor assembly 10 according to an embodiment of the invention. SAW sensor assembly 10 includes a SAW sensor 12, a circuit layer 14, and a Z-axis conductive elastomer 16 that electrically couples SAW sensor 12 to circuit layer 14.

SAW sensor 12 includes a plurality of electrodes 13A-13H (collectively electrodes 13), and circuit layer 14 includes a plurality of electrical contacts 15A-15H (collectively electrical contacts 15) formed on bottom side 19 of circuit layer 14. Electrodes 13 are generally located at a periphery of SAW sensor 12. Electrical contacts 15 of circuit layer 14 may include circuit traces 11A-11H (collectively circuit traces 11) positioned for coupling to electrodes 13 of SAW sensor 12.

The number of electrodes 13 and electrical contacts 15 depicted in FIG. 1 are not limiting of the invention as broadly embodied and claimed herein. In other words, any number of electrodes 13 and electrical contacts 15 could be used in accordance with the invention. As further shown in FIG. 1, SAW sensor 12 includes a waveguide layer 8 formed over one or more input and output transducers (not shown). By way of example, SAW sensor 12 may comprise a Love mode shear-horizontal surface acoustic wave (SH-SAW) sensor. In that case, the sensor includes input and output inter-digitated transducers (IDTs) on the substrate.

Circuit layer 14 generally refers to a layer including one or more circuit elements, such as circuit traces for routing electrical signals, resistors, capacitors, inductors, transistors, amplifies, or any other circuit elements. Circuit layer 14 may include components for driving and controlling SAW sensor 12, or may simply include circuit traces for routing signals to and from SAW sensor 12.

Circuit layer 14 is formed with an aperture 17. Z-axis conductive elastomer 16 electrically couples electrodes 13 to electrical contacts 15. In particular, Z-axis conductive elastomer 16 may be positioned to electrically couple electrodes 13 to circuit traces 11 of each of electrical contacts 15. Z-axis conductive elastomer 16 forms a hermetic barrier between SAW sensor 12 and circuit layer 14 proximate aperture 17. Accordingly, a fluid path over first side 18 of assembly 10, i.e., a top side, can be exposed to SAW sensor 12, but circuitry on second side 19 of assembly 10, i.e., a bottom side, can be isolated from the fluid flow. As used in this disclosure, a hermetic barrier refers to a substantial barrier to one or more types of fluids. In some cases, however, a hermetic barrier may allow some specific gases to pass through the barrier, albeit, while blocking most liquids and gases.

FIG. 2 is a perspective view illustrating the exemplary SAW sensor assembly of FIG. 1. Again, assembly 10 includes a SAW sensor 12, a circuit layer 14, and a Z-axis conductive elastomer 16 that electrically couples SAW sensor 12 to circuit layer 14. Z-axis conductive elastomer 16 forms a hermetic barrier between SAW sensor 12 and circuit layer 14 proximate aperture 17. Thus, a fluid path over first side 18 of assembly 10 can be exposed to SAW sensor 12, but circuitry on second side 19 of assembly 10 can be isolated from the fluid flow.

SAW sensor 12 may comprise any of a wide variety of SAW sensors. SH-SAW sensors are typically constructed from a piezoelectric material with a crystal-cut and orientation that allows the wave propagation to be rotated to a shear horizontal mode, i.e., parallel to the plane defined by the waveguide, resulting in reduced acoustic damping loss to a liquid in contact with the detection surface. Shear horizontal acoustic waves may include, e.g., thickness shear modes (TSM), acoustic plate modes (APM), surface skimming bulk waves (SSBW), Love-waves, leaky acoustic waves (LSAW), and Bleustein-Gulyaev (BG) waves.

In one example, sensor 12 comprises a Love mode shear-horizontal surface acoustic wave (SH-SAW) sensor. A SH-SAW sensor, for example, includes four main components: 1) a piezoelectric substrate; 2) an input inter-digitated transducer (IDT) on the substrate, which is used to excite an acoustic wave based on the piezoelectric effect; 3) an output IDT on the substrate, which receives the transmitted acoustic wave and generates electrical output by exploiting the piezoelectric effect; and 4) a wave-guide layer over the IDT's, which converts SH-type waves into waveguide Love modes for transmission from the input IDT to the output IDT.

In particular, Love wave sensors may include a substrate supporting a SH wave mode such as SSBW of ST quartz or the leaky wave of 36° YXLiTaO₃. These modes may preferably be converted into a Love-wave mode by application of thin acoustic guiding layer or waveguide. These waves are frequency dependent and can be generated if the shear wave velocity of the waveguide layer is lower than that of the piezoelectric substrate.

SAW sensor 12 may be designed for detection of any of a wide variety of chemical or biological agents. Various materials may be coated on the waveguide layer of SAW sensor 12 in order to facilitate detection of various chemical or biological agents. Waveguide materials may preferably be materials that exhibit one or more of the following properties: low acoustic losses, low electrical conductivity, robustness and stability in water and aqueous solutions, relatively low acoustic velocities,, hydrophobicity, higher molecular weights, highly cross-lied, etc. In one example, SiO₂ has been used as an acoustic waveguide layer on a quartz substrate. Examples of other thermoplastic and crosslinked polymeric waveguide materials include, e.g., epoxy, polymethyhlmethacrylate, phenolic resin (e.g., NOVALAC), polyimide, polystyrene, etc.

In particular, the presence of a particular material on the surface of the SAW sensor affects wave propagation through the waveguide layer, which facilitates detection of a specific chemical or biological agent. Accordingly, materials coated on the waveguide layer may be selected to attract, trap, bond with or otherwise attach to materials suspended in a fluid that flows across the waveguide. SAW sensor 12 may also comprise other types of such sensors. In any case, electrodes 13 provide an electrical interface to the components of SAW sensor 12.

Again, circuit layer 14 generally refers to a layer including one or more circuit elements, such as circuit traces for routing electrical signals, resistors, capacitors, inductors, transistors, amplifies, or any other circuit elements. Circuit layer 14 may include components for driving and controlling SAW sensor 12, or may simply include circuit traces for routing signals to and from SAW sensor 12. In any case, circuit layer 14 is formed with an aperture 17. For example, circuit layer 14 may comprise a flexible or rigid substrate coated with conductive material that is etched or printed to define various circuit traces on second side 19 of circuit layer 14. The substrate may hermetically isolate first side 18 of circuit layer 14 from such circuit traces on second side 19 of circuit layer 14.

Z-axis conductive elastomer 16 refers to a substantially continuous layer that is electrically conductive in the Z-axis (labeled on FIGS. 1 and 2), but substantially electrically insulative in all other directions, e.g., the X-axis and Y-axis. In other words, Z-axis conductive elastomer 16 conducts electricity only in the direction normal to its major surface. In some cases, electrical conduction is facilitated when Z-axis conductive elastomer 16 is compressed in the Z-axis, and in other cases, electrical conduction in the Z-axis occurs in an ordinary uncompressed state of Z-axis conductive elastomer 16.

In addition, Z-axis conductive elastomer 16 may be compliant. In any case, Z-axis conductive elastomer 16 generally seals and intimately engages the surfaces surface of circuit layer 14 and acoustic wave sensor 12. For example, Z-axis conductive elastomer 16 may comprise a substantially continuous layer positioned along an outer perimeter of aperture 17. In some embodiments, Z-axis conductive elastomer 16 is molded, punched, cut or otherwise processed to form a gasket-like ring sized to the extend about the perimeter of aperture 17. Z-axis conductive elastomer 16 electrically couples each of electrodes 13 on SAW sensor 12 to a corresponding one of electrical contacts 15 on circuit layer 14, e.g., via circuit traces 11. However, because Z-axis conductive elastomer 16 is substantially electrically insulative in the X-axis and Y-axis, electrical shorting between electrodes 13 or between electrical contacts 15 will not occur.

Z-axis conductive elastomer 16 may provide a hermetic seal between SAW sensor 12 and circuit layer 14. Accordingly, first surface 18 of assembly 10 maybe positioned along a fluid path, and second surface 19 of assembly 10 can be hermetically isolated from the fluid path because of the hermitically seal provided by Z-axis conductive elastomer 16.

Z-axis conductive elastomer 16 is also elastomeric. Accordingly, SAW sensor 12 is free to move slightly, relative to circuit layer 14 without breaking the hermetic seal between sensor 12 and circuit layer 14. Circuit layer 14 may be mechanically attached, e.g., to a sensor cartridge housing, without requiring SAW sensor 12 to be attached and inhibited by the rigidity of the cartridge housing.

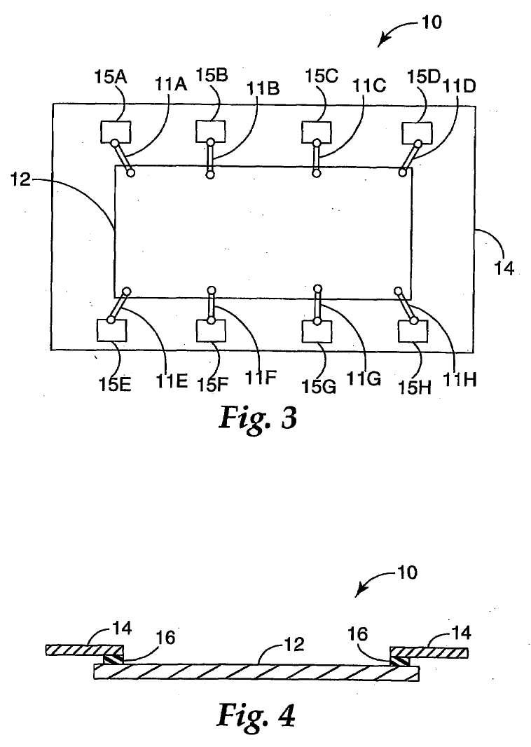

FIG. 3 is a bottom view of SAW sensor assembly 10. As shown in FIG. 3, electrical contacts 15 of circuit layer 14 are at least partially exposed on the bottom surface of assembly 10. In this example, circuit traces 11 corresponding to electrical contacts 15 extend radially inward to interface with the Z-axis conductive elastomer (not shown in FIG. 3). The Z-axis conductive elastomer, in turn, electrically couples electrical contacts 15 to electrodes (not shown in FIG. 3) of SAW sensor 12.

FIG. 4 is a cross-sectional side view of SAW sensor assembly 10. Assembly 10 includes a SAW sensor 12, a circuit layer 14, and a Z-axis conductive elastomer 16 that electrically couples SAW sensor 12 to circuit layer 14. Z-axis conductive elastomer 16 also provides a hermetic seal between SAW sensor 12 and circuit layer 14. Accordingly, first surface 18 of assembly 10 may be positioned along a fluid path, and second surface 19 of assembly 10 can be hermetically isolated from the fluid path because of the hermetic seal provided by Z-axis conductive elastomer 16. In addition, Z-axis conductive elastomer 16 is elastomeric. Accordingly, SAW sensor 12 is free to move slightly, relative to circuit layer 14 without breaking the hermetic seal between sensor 12 and circuit layer 14. Again, circuit layer 14 may be mechanically attached, e.g., to a sensor cartridge housing, without requiring SAW sensor 12 to be attached and inhibited by the rigidity of the cartridge housing.

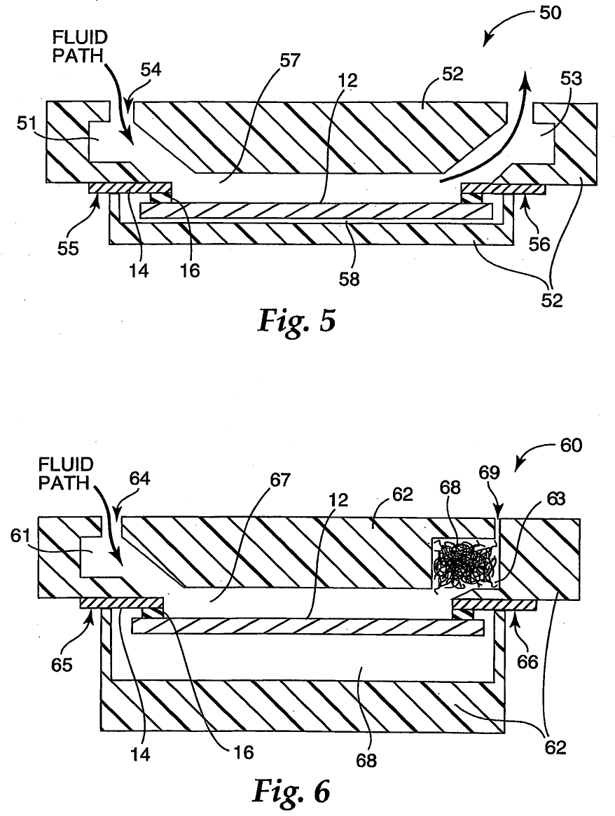

FIG. 5 is a cross-sectional side view illustrating an exemplary sensor cartridge 50 according to an embodiment of the invention. In particular, sensor cartridge 50 is one example of a device that can make use of SAW sensor assembly 10 as described herein.

Sensor cartridge 50 includes a housing 52 that defines a fluid path through cartridge 50 (illustrated by the arrows in FIG. 5). In this example, the fluid path includes an input reservoir 51, an output reservoir 53 and a channel 57 between the input reservoir 51 and output reservoir 53. An input port 54 is formed in housing 52 to receive the fluid. A SAW sensor assembly including a circuit layer 14 coupled to a SAW sensor 12 via a Z-axis conductive elastomer 16 is positioned along the fluid path through housing 52. In particular, aperture 17 (FIG. 1) of circuit layer 14 is positioned along the fluid path such that SAW sensor 12 is exposed to the fluid path.

Housing 52 may comprise a number of discrete components that individually couple to circuit layer 14 or other housing components, or may comprise an integrated housing structure. In any case, circuit layer 14 mechanically couples to housing 52. The elastomeric properties of Z-axis conductive elastomer 16 allow for slight movement of SAW sensor 12, relative to circuit layer 14 and housing 52 without breaking the hermetic seal between sensor 12 and circuit layer 14. Thus, SAW sensor 12 may be free to move slightly in response to pressure exerted by a fluid flow over sensor 12. An air reservoir 58 maybe formed in housing 52 on an opposing side of SAW sensor 12 relative to the fluid path. Air reservoir 58 improves isolation of SAW sensor 12 and helps avoid mechanical interaction between SAW sensor 12 and housing 52.

At least a portion of electrical contacts 15 (not shown in FIG. 5) can be exposed on an outer surface of cartridge 50, e.g., at locations 55 and 56. Accordingly, electrical coupling to circuit layer 14, and thus SAW sensor 12, through Z-axis conductive elastomer can be achieved at locations 55 and 56. A sensor module processing unit (not shown) can access the circuit layer 14 via circuit trace extensions that couple to electrical contact pads at locations 55 and 56. In this manner, the processing unit receives signals produced by SAW sensor 12 in order to generate a sensor result, i.e., presence, absence, or a level of a biological or chemical substance.

In operation, fluid is introduced through the fluid path in cartridge 52 (illustrated by the arrows in FIG. 5). The height of channel 57 may be defined to ensure a desired fluid flow over SAW sensor 12. As the fluid passes over SAW sensor 12, agents in the fluid may attach to the surface of the waveguide layer and thereby affect wave propagation through the waveguide layer of sensor 12, which facilitates detection of the given agent by circuitry on circuit layer 14, or external circuitry that interfaces with SAW sensor 12 via circuit layer 14 through Z-axis conductive elastomer 16.

FIG. 6 is another cross-sectional side view illustrating an exemplary sensor cartridge 60 according to an embodiment of the invention. Sensor cartridge 60 is another example of a device that can make use of SAW sensor assembly 10 as described herein.

Sensor cartridge 60 includes a housing 62 that defines a fluid path into cartridge 60 (illustrated by the arrow in FIG. 6). In this example, the fluid path includes an input reservoir 61, an output reservoir 63 and a channel 67 between the input reservoir 61 and output reservoir 63. An input port 64 is formed in housing 62 to receive the fluid. A SAW sensor assembly including a circuit layer 14 coupled to a SAW sensor 12 via a Z-axis conductive elastomer 16 is positioned along the fluid path through housing 62. In particular, aperture 17 (FIG. 1) of circuit layer 14 is positioned along the fluid path such that SAW sensor 12 is exposed to the fluid path.

Sensor cartridge 60 further includes a sorbent material 68 within output S reservoir 63. Sorbent material 68 tends to draw fluid from input reservoir 61 to output reservoir 63 via channel 67. Moreover, sorbent material 68 can absorb the fluid such that fluid introduced to input reservoir 61 is contained within sensor cartridge 60 following execution of the sensing functions performed by SAW sensor 12. An air vent 69 may also be formed proximate output reservoir 63 to improve fluid flow through the fluid path defined by input reservoir 61, output reservoir 63 and channel 67. The height of channel 67 may also be defined to ensure a desired fluid flow over SAW sensor 12.

Housing 62 may comprise a number of discrete components that individually couple to circuit layer 14, or may comprise an integrated housing structure. In any case, circuit layer 14 mechanically couples to housing 62. The elastomeric properties of Z-axis conductive elastomer 16 allow for slight movement of SAW sensor 12, relative to circuit layer 14 and housing 62 without breaking the hermitic seal between sensor 12 and circuit layer 14. Thus, SAW sensor 12 may be free to move slightly in response to pressure exerted by a fluid flow over sensor 12. An air reservoir 85 may be formed in housing 62 on an opposing side of SAW sensor 12 relative to the fluid path. Air reservoir 85 improves isolation of SAW sensor 12 and helps avoid mechanical interaction between SAW sensor 12 and housing 62.

At least a portion of electrical contacts 15 (not shown in FIG. 6) can be exposed on an outer surface of cartridge 60, e.g., at locations 65 and 66. Accordingly, electrical coupling to circuit layer 14, and thus SAW sensor 12, through Z-axis conductive elastomer can be achieved at locations 65 and 66.

In operation, fluid is introduced through the fluid path in cartridge 62 (illustrated by the arrow in FIG. 6). As the fluid passes over SAW sensor 12, agents in the fluid may affect wave propagation through the waveguide layer of sensor 12, which facilitates detection of the given agent by circuitry on circuit layer 14 or external circuitry that interfaces with SAW sensor 12 via circuit layer 14 through Z-axis conductive elastomer 16. Following detection of various agents in the fluid, by sensor 12, the fluid can be substantially contained in sorbent material 68 within output reservoir 63.

### EXAMPLE

A flexible circuit layer was constructed using a polyimide substrate previously sputtered with copper. The copper side of the structure was masked with a polymer where circuit traces were desired. The non-masked copper was then etched away in a sodium acetate bath. The resultant circuit layer included eight traces on the polyimide substrate, corresponding to electrode connectors of a SAW sensor.

A layer of Z-axis conductive elastomer was bonded to the circuit layer over the circuit traces by applying slight pressure on the Z-axis conductive elastomer while heating the material to a temperature of 80 degree Celsius according to manufacturing instructions of the Z-axis conductive elastomer. The Z-Axis conductive elastomer is heated via a platen that is heated to 80 degrees Celsius, this platen also provides the slight pressure needed to bond the circuit and Z-Axis conductive elastomer. The Z-axis conductive elastomer comprised 40 micron silver-coated glass beads within a thermoplastic matrix, commercially available from 3M Company of Saint Paul, Minn. An aperture was then punched in the circuit layer corresponding to the waveguide surface of the SAW sensor.

A Love mode shear-horizontal surface acoustic wave (SH-SAW) sensor available from Sandia National Laboratories, Albuquerque, N.Mex. was placed onto the substrate over the aperture such that electrodes of the SH-SAW sensor coupled to the Z-axis conductive elastomer. The assembly was placed under a heated platen that applied pressure and heat to the assembly, thus processing the Z-Axis conductive elastomer to the circuit and SH-SAW. During this processing, the Z-Axis conductive elastomer was heated to a temperature of 140 degrees Celsius while the platen placed 250 psi of pressure on the bond area The platen applied this heat and pressure for 10 seconds to fully process the Z-Axis conductive elastomer. The assembly was then allowed to cool. Electrical connection between the circuit layer and the SH-SAW sensor was verified with a digital voltmeter.

Various embodiments of the invention have been described. In particular, a SAW sensor assembly that makes use of a Z-axis conductive layer has been described. In many embodiments described herein, the Z-axis conductive layer is described as a Z-axis conductive elastomer. However, in other embodiments, the Z-axis conductive layer is not necessarily elastomeric. These and other embodiments are within the scope of the following claims.

The present invention may be utilized in combination with various materials, methods, systems, apparatus, etc. as described in various U.S. and PCT patent applications identified below, all of which are incorporated by reference in their respective entireties. They include: U.S. patent application Ser. No. 60/533,162, filed on Dec. 30, 2003; U.S. patent application Ser. No. 60/533,178, filed on Dec. 30, 2003; U.S. patent application Ser. No. 10/896,392, filed Jul. 22, 2004; U.S. patent application Ser. No. 10/713,174, filed Nov. 14, 2003; U.S. patent application Ser. No. 10/987,522, filed Nov. 12, 2004; U.S. patent application Ser. No. 10/714,053, filed Nov. 2003; U.S. patent application Ser. No. 10/987,075, filed Nov. 12, 2004; U.S. patent application Ser. No. 60/533,171, filed Dec. 30, 2003; U.S. patent application Ser. No. 10/960,491, filed Oct. 7, 2004; U.S. patent application Ser. No. 60/533,177, filed Dec. 30, 2003; U.S. patent application Ser. No. 60/533,169, filed Dec. 30, 2003; _____, title “Method of Enhancing Signal Detection of Cell-Wall Components of Cells”, filed on even date herewith (Attorney Docket No. 59467US002); _____, titled “Soluble Polymers as Amine Capture Agents and Methods”, filed on even date herewith (Attorney Docket No. 59995US002); _____, titled “Multifunctional Amine Capture Agents”, filed on even date herewith (Attorney Docket No. 59996US002); PCT Application No. _____, titled “Estimating Propagation Velocity Through A Surface Acoustic Wave Sensor”, filed on even date herewith (Attorney Docket No. 58927WO003); PCT Application No. _____, titled “Acousto-Mechanical Detection Systems and Methods of Use”, filed on even date herewith (Attorney Docket No. 59468WO003); PCT Application No. _____, titled “Detection Cartridges, Modules, Systems and Methods”, filed on even date herewith (Attorney Docket No. 60342WO003); and PCT Application No. ______, titled “Acoustic Sensors and Methods”, filed on even date herewith (Attorney Docket No. 60209WO003).

As used herein and in the appended claims, the singular forms “a,” “and,” and “the” include plural referents unless the context clearly dictates otherwise.

The terms “comprises” and variations thereof do not have a limiting meaning where these terms appear in the description or the claims.

The complete disclosures of the patents, patent applications, patent documents, and publications cited herein are incorporated by reference in their entirety as if each were individually incorporated. Various modifications and alterations to this invention will become apparent to those skilled in the art without departing from the scope of this invention. It should be understood that this invention is not intended to be unduly limited by the illustrative embodiments set forth herein and that such embodiments are presented by way of example only, with the scope of the invention intended to be limited only by the claims.

1. A surface acoustic wave sensor assembly comprising:
a surface acoustic wave sensor comprising a plurality of electrodes;
a circuit layer including an aperture and a plurality of electrical contacts; and
a Z-axis conductive layer to couple the electrical contacts to the electrodes.

2. The surface acoustic wave sensor assembly of claim 1, wherein the Z-axis conductive layer comprises a Z-axis conductive elastomer.

3. The surface acoustic wave sensor assembly of claim 2, wherein the Z-axis conductive elastomer forms a hermetic barrier between the surface acoustic wave sensor and the circuit layer.

4. The surface acoustic wave sensor assembly of claim 1, wherein the surface acoustic wave sensor forms part of a sensor cartridge and the surface acoustic wave sensor is exposed to a fluid path within the cartridge via the aperture.

5. The surface acoustic wave sensor assembly of claim 1, wherein the surface acoustic wave sensor comprises a Love mode shear-horizontal surface acoustic wave sensor.

6. The surface acoustic wave sensor assembly of claim 1, wherein the electrical contacts of the circuit layer comprise circuit traces formed on the circuit layer.

7. The surface acoustic wave sensor assembly of claim 1, wherein the electrodes are located at a periphery of the sensor.

8. A sensor cartridge comprising:
a housing comprising a fluid path; and
a surface acoustic wave sensor assembly comprising a surface acoustic wave sensor that comprises a plurality of electrodes, a circuit layer that comprises an aperture and a plurality of electrical contacts, and a Z-axis conductive layer to couple the electrical contacts to the electrodes, wherein the surface acoustic wave sensor is exposed to the fluid path via the aperture.

9. The sensor cartridge of claim 8, wherein the plurality of electrical contacts are not exposed to the fluid path.

10. The sensor cartridge of claim 8, wherein the Z-axis conductive layer comprises a Z-axis conductive elastomer.

11. The sensor cartridge of claim 10, wherein the Z-axis conductive elastomer forms a hermetic barrier between the surface acoustic wave sensor and the circuit layer.

12. The sensor cartridge of claim 8, wherein the surface acoustic wave sensor comprises a Love mode shear-horizontal surface acoustic wave sensor.

13. The sensor cartridge of claim 8, wherein the housing comprises an input port to the fluid path.

14. The sensor cartridge of claim 13, wherein the fluid path comprises an input reservoir proximate the input port, an output reservoir, and a channel between the input reservoir and output reservoir, wherein the aperture is proximate the channel.

15. The sensor cartridge of claim 14, further comprising sorbent material inside the output reservoir.

16. The sensor cartridge of claim 15, wherein the housing comprises an output vent proximate the output reservoir.

17. The sensor cartridge of claim 8, wherein the housing comprises an air reservoir an opposing side of the surface acoustic wave sensor relative to the fluid path.

18. The sensor cartridge of claim 8, wherein the electrical contacts of the circuit layer comprise circuit traces formed on the circuit layer.

19. A method of forming a surface acoustic wave assembly comprising electrically coupling a plurality of electrodes of a surface acoustic wave sensor to a plurality of electrical contacts of a circuit layer with a Z-axis conductive layer.

20. The method of claim 19, further comprising providing an aperture in the circuit layer such that when the a plurality of electrodes are coupled to the plurality of electrical contacts of a circuit layer with a Z-axis conductive layer, the surface acoustic wave sensor is exposed via the aperture.

21. The method of claim 19, wherein the Z-axis conductive layer comprises a Z-axis conductive elastomer.

22. The method of claim 21, wherein the Z-axis conductive elastomer forms a hermetic barrier between the surface acoustic wave sensor and the circuit layer.

23. The method of claim 19, wherein the surface acoustic wave sensor comprises a Love mode shear-horizontal surface acoustic wave sensor.
